(19) United States
(12) Patent Application Publication
(10) Pub. No.: US 2009/0312967 A1
(43) Pub. Date: Dec. 17, 2009

(54) PRODUCING A PHASOR REPRESENTATION OF AN ELECTRICAL ENTITY IN A MULTIPHASE AC ELECTRIC POWER SYSTEM

(76) Inventor: Ziwen Yao, Surrey (CA)

Correspondence Address: WOODCOCK WASHBURN LLP, CIRA CENTRE, 12TH FLOOR, 2929 ARCH STREET, PHILADELPHIA, PA, 19104-2891, US

(21) Appl. No.: 12/376,055

(22) PCT Filed: Aug. 2, 2006
(86) PCT No.: PCT/CA06/01275

§ 371 Date: Feb. 2, 2009

(51) Int. Cl. G06F 19/00; G01R 21/00; G01R 13/00; G06F 15/00

(52) U.S. Cl. 702/60; 702/66; 702/189; 702/188

(57) ABSTRACT

A phasor representation of an electrical entity at a geographical location in a multiple phase AC electric power system is produced by receiving a synchronization signal from a remote source, producing a sampling time signal in response to the synchronization signal and a local reference time signal, and producing samples representing an amount of the entity in respective ones of the phases in the AC power system in response to the sampling time signal and the electrical entity in respective ones of the phases in the AC power system. A transformation is performed on the samples to produce a two-axis rotating reference frame representation of the electrical entity in a two-axis rotating reference frame. For each sample, a representation of a sampling time associated with the sample is produced. The two-axis rotating reference frame representation and the representation of the sampling time comprise the phasor representation.

### BACKGROUND OF THE INVENTION

1. Field of Invention

This invention relates to monitoring multiphase AC electric power systems and more particularly to methods and apparatuses for producing a phasor representation of an electrical entity in a multiphase AC electric power system.

2. Description of Related Art

The global electric industry is facing a number of challenges including an aging infrastructure, growing demand, and rapidly changing markets, all of which threaten to reduce the reliability of the electricity supply.

Deregulation of the electricity supply industry is occurring and there has been a drive to increase efficiencies in power systems. New processes for intelligent observation and management of the electricity supply and power grid have been emerging.

Ever growing demand due to economic and demographic variations, without additional generation investments, has led transmission and distribution systems worldwide to their limits of reliable operation. Operation and security management is becoming increasingly important.

The primary objective of operation and security management is to maximize infrastructure use while concurrently reducing the risk of system instability and blackouts. Special protection schemes (SPS) or wide area control systems (WACS) are used to guard system stability including angle, frequency and voltage stability.

According to the North American Electric Reliability Council (NERC), transmission congestion is expected to continue over the next decade. Growth in demand and the increasing number of energy transactions continue to outstrip the proposed expansion of many transmission systems. The Edison Electric Institute indicates that the U.S. transmission system requires nearly $56 billion in new investment over the next decade, but only $35 billion is likely to be spent. Figures from the Federal Energy Regulatory Commission (FERC) place total transmission congestion costs nationwide at several hundred million dollars.

In a report on the Eastern Blackout of 2003, NERC recommended the installation of more Phasor Measurement Units (PMUs) in power grids to monitor the stability of the grid. Accordingly, an increasing number of PMUs have been installed in industrial power grids in North America.

It is well known that the technology of measuring of voltage and/or current magnitudes is pretty mature, whereas phasor measurement is not. Some PM devices that make phasor measurements have been commercialized and installed in industrial power grids. The accuracy and dynamic performance of any phasor measurement apparatus directly affects the quality of monitoring and controlling in the power system. Any erroneous phasor measurements taken during power system disturbances or emergency conditions will degrade control decisions and may worsen the emergency conditions.

The algorithms used by most PMUs today employ Fourier Transformations. It is well known that the phasor of an AC signal calculated using a Fourier Transformation is dependent on the frequency and magnitude of the signal. It can provide accurate measurement only when the frequency and magnitude of the signal is constant. If the frequency and magnitude of the signal are varying in real-time, as they do in any power grid, any phasor calculated using a Fourier Transformation algorithm can be erroneous.

Therefore, there is a need to move away from the use of Fourier Transformations in primary phasor calculations.

### SUMMARY OF THE INVENTION

In accordance with one aspect of the invention, there is provided an apparatus for producing a phasor representation of an electrical entity at a geographical location in a multiple phase AC electric power system. The apparatus includes a receiver, a local reference time signal generator, a sampling time signal generator, a sampling circuit, a processor, and a time stamp generator. The receiver is operably configured to receive a synchronization signal from a remote source. The local reference time signal generator is operably configured to generate a local reference time signal. The sampling time signal generator is operably configured to produce a sampling time signal in response to the synchronization signal and the local reference time signal. The sampling circuit is operably configured to produce samples representing an amount of the electrical entity in respective ones of the phases in the AC power system in response to the sampling time signal and the entity in respective ones of the phases in the AC power system. The processor is operably configured to perform a transformation on the samples to produce a two-axis rotating reference frame representation of the electrical entity in a two-axis rotating reference frame. The time stamp generator is operably configured to produce time stamps representing time at which the respective samples are taken by the sampling circuit. The two-axis rotating reference frame representation and the time stamp comprise the phasor representation.

The receiver may be operably configured to receive a synchronization signal that is also received by at least one other apparatus operable to produce a phasor representation of an electrical entity at a different geographical location in the multiple phase AC electric power system.

The receiver may be operably configured to receive a wirelessly transmitted synchronization signal.

The receiver may be operably configured to receive a global positioning system (GPS) signal from a GPS system.

The sampling time signal generator may include a counter incremented in response to the local reference time signal and a circuit operably configured to determine a difference in counts between the counter incremented in response to the local reference time signal and a counter associated with the synchronization signal, in response to receipt of the synchronization signal. The sampling time signal generator may also include a circuit operably configured to add to a count value produced by the counter incremented by the local clock signal, a fraction of the difference in counts, to produce a sample count value, and a circuit operably configured to cause a sample of the entity to be produced when the sample count value satisfies a criterion.

The processor may be operably configured to perform a Blondel-Park Transformation on the sampled signals.

The processor may be operably configured to set transformation coefficients of the Blondel-Park Transformation in response to the sampling time signal and a frequency value representing a rotation frequency of the two-axis rotating reference frame.

The two-axis rotating reference frame representation may include a direct axis component and a quadratic axis component.

The two-axis rotating reference frame representation may include a modulus component and an angle component.

The processor may be operably configured to cancel contributions of harmonics included in the two-axis rotating reference frame representation.

The processor may be operably configured to store successive ones of the two-axis rotating reference frame representation and sum particular ones of the successive ones of the two-axis rotating reference frame representation.

The apparatus may further include a first-in-first-out buffer in communication with the processor for storing successive ones of the two-axis rotating reference frame representation.

The processor may be operably configured to separately sum a component of a two-axis rotating reference frame representation associated with time t, with a component of a two-axis rotating reference frame representation associated with time t-Δ₁, to produce a first suppressed harmonic representation of said component of said two axis rotating reference frame representation.

The entity t-Δ₁ may represent a time Δ₁ sample periods before time t.

The entity Δ₁ may represent ¼ of a period of a fundamental frequency of the electrical entity.

The apparatus may further include a fundamental frequency signal generator in communication with the processor and operably configured to determine a fundamental frequency of the electrical entity. The processor may be operably configured to set Δ₁ in response to the fundamental frequency.

The processor may be operably configured to cancel contributions of harmonics included in the first suppressed harmonic representation to produce a second suppressed harmonic representation.

The processor may be operably configured to store successive ones of the first suppressed harmonic representation and sum particular ones of the successive ones of the first suppressed harmonic representation.

The apparatus may further include a first-in-first-out buffer for storing the first suppressed harmonic representation.

The processor may be operably configured to separately sum a component of a first suppressed harmonic representation associated with time t, with a component of a first suppressed harmonic representation associated with time t-Δ₂ to produce the second suppressed harmonic representation.

The entity t-Δ₂ may represent a time Δ₂ sample periods before time t.

The entity Δ₂ may represent 1/24 of a period of a fundamental frequency of the electrical entity.

The apparatus may further include a fundamental frequency signal generator in communication with the processor and operably configured to determine a fundamental frequency of the electrical entity. The processor may be operably configured to set Δ₂ in response to the fundamental frequency.

In accordance with another aspect of the invention, there is provided a method of producing a phasor representation of an electrical entity at a geographical location in a multiple phase AC electric power system. The method involves receiving a synchronization signal from a remote source, producing a sampling time signal in response to the synchronization signal and a local reference time signal, and producing samples representing an amount of the entity in respective ones of the phases in the AC power system in response to the sampling time signal and the electrical entity in respective ones of the phases in the AC power system. The method further involves performing a transformation on the samples to produce a two-axis rotating reference frame representation of the electrical entity in a two-axis rotating reference frame. The method also involves, for each sample, producing a representation of a sampling time associated with the sample. The two-axis rotating reference frame representation and the representation of the sampling time comprise the phasor representation.

Receiving the synchronization signal may involve receiving a synchronization signal that is also received by at least one other apparatus operable to produce a phasor representation of an electrical entity at a different geographical location in the multiple phase AC electric power system.

Receiving the synchronization signal may involve receiving a wirelessly transmitted synchronization signal.

Receiving the wirelessly transmitted synchronization signal may involve receiving a global positioning signal (GPS) signal from a GPS system.

Producing the sampling time signal may involve determining a difference in counts between a counter incremented by the local reference time signal and a counter associated with the synchronization signal in response to receipt of the synchronization signal.

Producing the sampling time signal may involve adding to a count value produced by the counter incremented by the local reference time signal a fraction of the difference in counts to produce a sample count value and causing a sample of the entity to be produced when the sample count value satisfies a criterion.

Performing a transformation may involve performing a Blondel-Park Transformation on the sampled signals.

Performing a Blondel-Park transformation may involve setting transformation coefficients of the Blondel-Park Transformation in response to the sampling time signal and a frequency value representing a rotation frequency of the two-axis rotating reference frame.

The method may further involve canceling contributions of harmonics included in the two-axis rotating reference frame representation.

Canceling contributions of harmonics may involve storing successive ones of the two-axis rotating reference frame representation and summing particular ones of the successive ones of the two-axis rotating reference frame representation.

Storing successive ones of the two-axis rotating reference frame representation may involve storing the two-axis rotating reference frame representations in a first-in-first-out buffer.

Summing particular ones of the successive ones of the two-axis rotating reference frame representation may involve separately summing a component of a two-axis rotating reference frame representation associated with time t, with a component of a two-axis rotating reference frame representation associated with time t-Δ₁, to produce a first suppressed harmonic representation of the component of the two-axis rotating reference frame representation.

The method may further involve determining a fundamental frequency of the electrical entity and setting Δ₁ in response to the fundamental frequency.

The method may also involve canceling contributions of harmonics included in the first suppressed harmonic representation to produce a second suppressed harmonic representation.

Canceling contributions of harmonics may involve storing successive ones of the first suppressed harmonic representation and summing particular ones of the successive ones of the first suppressed harmonic representation.

Storing successive ones of the first suppressed harmonic representation may involve storing the first suppressed harmonic representation in a first-in-first-out buffer.

Summing particular ones of the successive ones of the first suppressed harmonic representation may involve separately summing a component of a first suppressed harmonic representation associated with time t, with a component of a first suppressed harmonic representation associated with time t-Δ₂ to produce the second suppressed harmonic representation of the two-axis rotating reference frame representation.

The method may further involve determining a fundamental frequency of the electrical entity and setting Δ₂ in response to the fundamental frequency.

In accordance with another aspect of the invention, there is provided a method of canceling contributions of harmonics included in a succession of two-axis rotating reference frame representations of an electrical entity in a multiple phase AC electric power system. The method involves associating successive ones of the two-axis rotating reference frame representations with respective times t, and separately summing components of a two-axis rotating reference frame representation associated with time t, with corresponding components of a two-axis rotating reference frame representation associated with time t-Δ₁, to produce a first suppressed harmonic representation of the two-axis rotating reference frame representations.

Associating may involve storing successive ones of the two-axis rotating reference frame representations in a first-in-first-out buffer.

The method may further involve canceling contributions of harmonics included in the first suppressed harmonic representation.

Storing successive ones of the first suppressed harmonic representation may involve storing the first suppressed harmonic representation in a first-in-first-out buffer.

Summing particular ones of the successive ones of the first suppressed harmonic representation may involve separately summing a component of a first suppressed harmonic representation associated with time t, with a component of a first suppressed harmonic representation associated with time t-Δ₂ to produce a second suppressed harmonic representation of the component of the first suppressed harmonic representation.

The method may further involve determining a fundamental frequency of the electrical entity and setting Δ₂ in response to the fundamental frequency.

The present invention does not use Fourier Transforms to produce phasor representations and thus des not suffer from the drawbacks associated with such Transforms. Instead a special transform is used to represent the measured electrical entities in a two-axis rotating reference frame and processing is done on the result of the transformation to reduce the contributions of harmonics to the two-axis rotating reference frame representation, providing greater accuracy and robustness. This can improve the use of phasor measurements in Special Protections Systems (SPS) and Wide Area Control Systems (WACS) and digital protection relay apparatuses. In particular, the methods and apparatus proposed herein reduce phasor measurement delay and can increase response times in such control systems. In digital protection relay apparatuses reduced phasor measurement delay can facilitate reduced fault clearing time resulting in more effective protection against power system disturbances.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

In drawings which illustrate embodiments of the invention,

FIG. 1 is a schematic representation of a system according to a first embodiment of the invention including an apparatus according to the first embodiment of the invention for producing a phasor representation of an electrical entity at a geographical location in a multiple phase AC electric power system, for receipt by a monitoring station of the system.

FIG. 2 is a flow chart of a method according to the first embodiment of the invention, for producing a phasor representation of an electrical entity at the geographical location in the multiple phase AC electric power system.

FIG. 3 is a schematic representation of a method for suppressing harmonics in a two-axis rotating reference frame representation produced by the apparatus shown in FIG. 1.

FIG. 4 is a schematic representation of a method for suppressing harmonics in the two-axis rotating reference frame representation produced by the apparatus shown in FIG. 1, according to an alternative embodiment.

FIG. 5 is a block diagram of the apparatus shown in FIG. 1.

FIG. 6 is a flow chart representing codes executed by the processor shown in FIG. 5 for carrying out a synchronization signal routine.

FIG. 7 is a flow chart representing codes executed by the processor shown in FIG. 5 to implement a phased lock loop routine for locking a locally generated clock signal with a synchronization signal received from a remote source.

FIG. 8 is a flow chart representing codes executed by the processor shown in FIG. 5 for performing a Blondel-Park Transformation on sampled electrical entities of the multiphase electric power distribution system to produce a first two-axis rotating reference frame representation.

FIG. 9 is a flow chart illustrating codes executed by the processor shown in FIG. 5 for preparing and transmitting packets containing the two-axis rotating reference frame representation to the monitoring station shown in FIG. 1.

FIG. 10 is a flow chart representing codes executed by the processor shown in FIG. 5 for causing the processor to suppress the contributions of the negative sequence, 5^{th} and 7^{th} harmonics of the electrical entity being measured, from the two-axis rotating reference frame representation.

FIG. 11 is a flow chart representing codes executed by the processor shown in FIG. 5 for carrying out a second suppressed harmonic routine to suppress contributions of the 11^{th} and 13^{th} harmonics of the electrical entity being measured, from the two-axis rotating reference frame representation.

### DETAILED DESCRIPTION

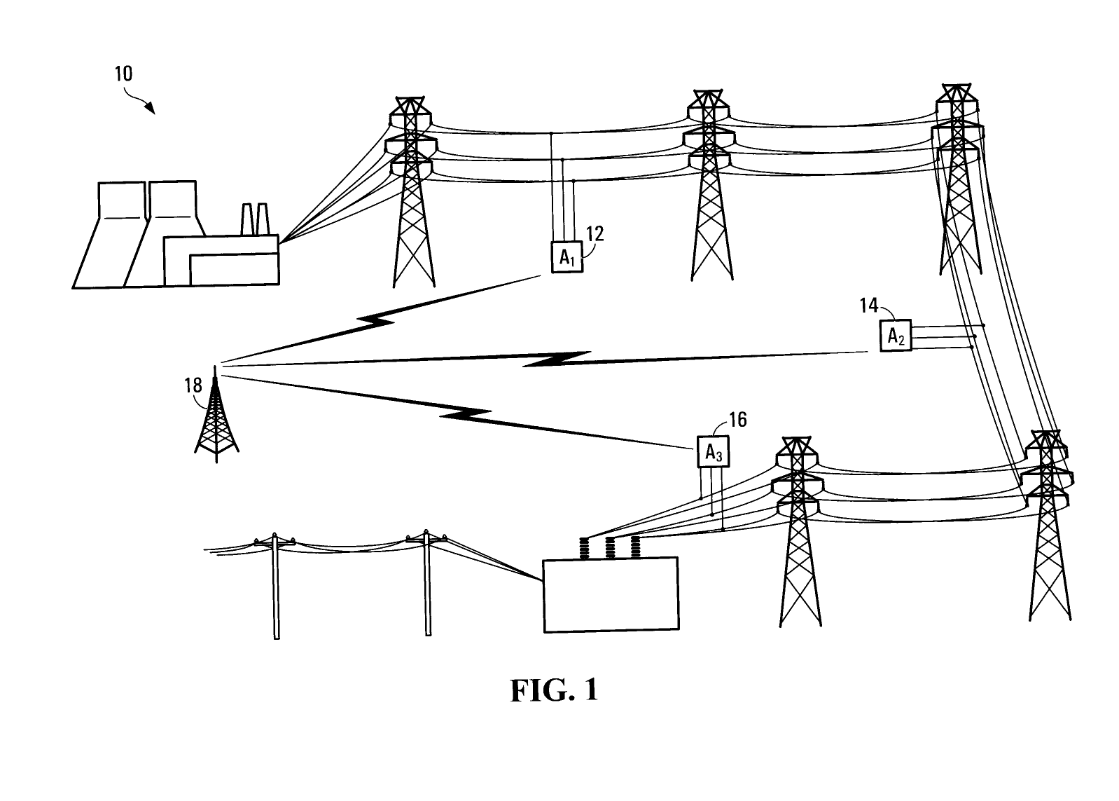

Referring to FIG. 1, a system for monitoring an electrical property of an electrical power distribution system according to a first embodiment of the invention is shown generally at 10.

In the embodiment shown, the system 10 includes a plurality of measurement apparatuses 12, 14, and 16 operable to measure instantaneous phasors of multiphase electrical entities at various geographically separated points in the electrical power distribution system.

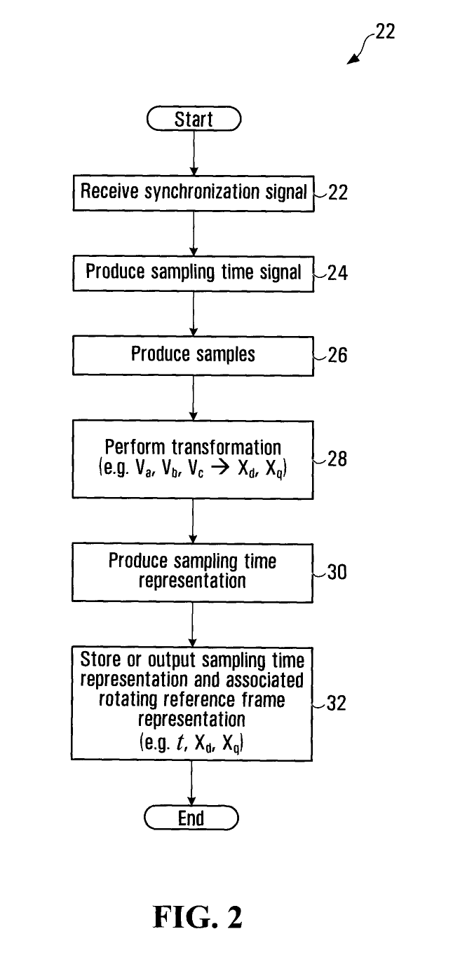

Referring to FIG. 2, a method executed by each measurement apparatus is shown generally at 20. As shown at 22, the apparatus receives a synchronization signal from a remote source such as a satellite in geosynchronous orbit about the earth, or land-based sources such as Long Range Area Navigation (LORAN) signal transmitters. Where the synchronization signal is received from a satellite, the synchronization signal may be a signal produced by a Global Positioning System such as a type including a count value in microseconds at accurate, 1-second intervals.

As shown at 24, in response to the synchronization signal and a local reference time signal generated at each apparatus, a sampling time signal is produced.

As shown at 26, measurements are taken of an electrical entity such as current or voltage measured on a nearby portion of a powerline or a busbar of the electrical transmission and distribution system and these measurements are sampled to produce samples representing an amount of the entity in respective ones of the phases in the AC power system in response to the sampling time signal and the measured value of the entity in respective ones of the phases in the AC power system.

As shown at 28, the apparatus then performs a transformation on the samples to produce a two-axis rotating reference frame representation of the entity in a two-axis rotating reference frame. This transformation may be a Blondel-Park transformation, for example, which transforms voltage samples for each phase (x_{A}(tₛ), x_{B}(tₛ) and x_{C}(tₛ)) into d, q and o values that act as the two-axis rotating reference frame representation of voltage. An exemplary Blondel-Park transformation is shown below:

$$[ \begin{matrix}{x}_{d} ( {t}_{S} ) \\ {x}_{q} ( {t}_{S} ) \\ {x}_{0} ( {t}_{S} )\end{matrix} ] = α [ \begin{matrix}cos ( {ω}_{0} {t}_{S} ) & cos ( {ω}_{0} {t}_{S} - \frac{2}{3} π ) & cos ( {ω}_{0} {t}_{S} + \frac{2}{3} π ) \\ - sin ( {ω}_{0} {t}_{S} ) & - sin ( {ω}_{0} {t}_{S} - \frac{2}{3} π ) & - sin ( {ω}_{0} {t}_{S} + \frac{2}{3} π ) \\ \frac{1}{2} & \frac{1}{2} & \frac{1}{2}\end{matrix} ] [ \begin{matrix}{x}_{A} ( {t}_{S} ) \\ {x}_{B} ( {t}_{S} ) \\ {x}_{C} ( {t}_{S} )\end{matrix} ]$$

The two-axis rotating reference frame representation produced by the Blondel-Park transformation may represent a virtual rotor position, for example, of a generator situated right at the geographical location at which the measurements are taken.

After producing the two-axis rotating reference frame representation, the representation may be processed in a plurality of different ways. For example as shown at 30, for each sample, a representation of a sampling time associated with the sample may be produced and the two-axis rotating reference frame representation and the representation of the sampling time may comprise a phasor representation representing instantaneous virtual rotor position, for example at the geographical location at which the apparatus is located. As shown at 32, this phasor representation may then be stored or transmitted to a monitoring station 18 shown in FIG. 1 which receives phasor representations of this type from the plurality of apparatuses at the different geographical locations. The monitoring station may compare the phasor representations to compare virtual rotor positions associated with each of the respective geographical locations to assess stability status of the system 10.

In an alternative embodiment, instead of simply forwarding the phasor representation to the monitoring station, each apparatus may perform further processing to suppress the contributions of harmonics and a negative sequence component in the measured entities in the final result of the transformation, thereby producing a cleaner, more reliable phasor representation. The suppression of the contributions of harmonics and the negative sequence component may be referred to as harmonic trapping.

As an example of harmonic trapping, it will be appreciated that the originally measured voltage or current values for each phase may comprise a superposition of a plurality of components including a fundamental component, harmonics of the fundamental component and a negative sequence component of the fundamental component. In most North American power systems, the fundamental component is nominally 60 Hz, for example.

From the Blondel-Park transformation it will be seen that the transformation includes terms that have a (−⅔π) and a (+⅔π) delay component. These terms effectively cause odd multiples of the third harmonic (h=3, 9, 15, 18, etc.) to be cancelled and therefore the transform itself causes the cancellation of at least some of the possible harmonics that may be present in the measured electrical entity being measured. Since these harmonics are ultimately cancelled by the transformation, they can be ignored.

In most power systems, if even ordered harmonics (i.e 2, 4, 6, 8, 10 etc.) are present in the measured electrical entity, in general, the system is known to have problems of equipment abnormality such as, malfunctioning or even failure and this would be detected by conventional monitoring devices locally installed close to the abnormal equipment. Therefore even ordered harmonics are not of concern to the apparatus described herein.

In effect, the dominant harmonics of interest for suppression are those of order −1, 5, 7, 11, 13, 17, 19, 23, 25, etc, where the harmonic of order (−1) refers to the negative sequence component. This is suggested by IEEE recommended Practices and Requirements for Harmonic Control in Electrical Power Systems, IEEE Standard 519,1992. At least, the most dominant components of these harmonics are cancelled in accordance with the present invention.

To explain how the harmonics are cancelled, representation of input voltages x_{A}(t), x_{B}(t) and x_{C}(t) for example, may be written to include terms associated with the dominant harmonics as follows:

$${x}_{A} ( t ) = {a}_{1} sin ( ω t + {ϕ}_{1} ) + {a}_{- 1} sin ( ω t + {ϕ}_{- 1} ) ++ {a}_{5} sin ( 5 ω t + {ϕ}_{5} ) + {a}_{7} sin ( 7 ω t + {ϕ}_{7} ) ++ {a}_{11} sin ( 11 ω t + {ϕ}_{11} ) + {a}_{13} sin ( 13 ω t + {ϕ}_{13} ) + O ( f \geq 17 \cdot {f}_{0} )$$

$${x}_{B} ( t ) = {a}_{1} sin ( ω t + {ϕ}_{1} - \frac{2}{3} π ) + {a}_{- 1} sin ( ω t + {ϕ}_{- 1} + \frac{2}{3} π ) ++ {a}_{5} sin ( 5 ω t + {ϕ}_{5} + \frac{2}{3} π ) + {a}_{7} sin ( 7 ω t + {ϕ}_{7} - \frac{2}{3} π ) ++ {a}_{11} sin ( 11 ω t + {ϕ}_{11} + \frac{2}{3} π ) + {a}_{13} sin ( 13 ω t + {ϕ}_{13} - \frac{2}{3} π ) + O ( f \geq 17 \cdot {f}_{0} )$$

$${x}_{C} ( t ) = {a}_{1} sin ( ω t + {ϕ}_{1} + \frac{2}{3} π ) + {a}_{- 1} sin ( ω t + {ϕ}_{- 1} - \frac{2}{3} π ) ++ {a}_{5} sin ( 5 ω t + {ϕ}_{5} - \frac{2}{3} π ) + {a}_{7} sin ( 7 ω t + {ϕ}_{7} + \frac{2}{3} π ) ++ {a}_{11} sin ( 11 ω t + {ϕ}_{11} - \frac{2}{3} π ) + {a}_{13} sin ( 13 ω t + {ϕ}_{13} + \frac{2}{3} π ) + O ( f \geq 17 \cdot {f}_{0} )$$

Application of the Blondel-Park transformation to these representations may be represented as follows:

$${X}_{dq 0} ( t ) = [ \begin{matrix}{x}_{d} ( t ) \\ {x}_{q} ( t ) \\ {x}_{0} ( t )\end{matrix} ] = B \cdot {X}_{ABC} ( t )$$

If, in the transformation a is set to ⅓, a direct component x_{d}(t) may be produced according to the relation:

This may be somewhat simplified by use of the formula:

$$cos ( γ ) sin ( θ ) = \frac{1}{2} [ sin ( θ + γ ) + sin ( θ - γ ) ] ,$$

resulting in

$$3 {x}_{d}^{0} ( t ) = {a}_{1} cos ( ω t ) sin ( ω t + {ϕ}_{1} ) + cos ( ω t ) [ \begin{matrix}{a}_{- 1} sin ( ω t + {ϕ}_{- 1} ) ++ {a}_{5} sin ( 5 ω t + {ϕ}_{5} ) + \\ {a}_{7} sin ( 7 ω t + {ϕ}_{7} ) ++ {a}_{11} sin ( 11 ω t + {ϕ}_{11} ) + \\ {a}_{13} sin ( 13 ω t + {ϕ}_{13} ) + O ( f \geq 17 \cdot {f}_{0} )\end{matrix} ] ++ {a}_{1} cos ( ω t - \frac{2}{3} π ) sin ( ω t + {ϕ}_{1} - \frac{2}{3} π ) + cos ( ω t - \frac{2}{3} π ) [ \begin{matrix}{a}_{- 1} sin ( ω t + {ϕ}_{- 1} + \frac{2}{3} π ) ++ {a}_{5} sin ( 5 ω t + {ϕ}_{5} + \frac{2}{3} π ) + {a}_{7} \\ sin ( 7 ω t + {ϕ}_{7} - \frac{2}{3} π ) ++ {a}_{11} sin ( 11 ω t + {ϕ}_{11} + \frac{2}{3} π ) + \\ {a}_{13} sin ( 13 ω t + {ϕ}_{13} - \frac{2}{3} π ) + O ( f \geq 17 \cdot {f}_{0} )\end{matrix} ] ++ {a}_{1} cos ( ω t + \frac{2}{3} π ) sin ( ω t + {ϕ}_{1} + \frac{2}{3} π ) + cos ( ω t + \frac{2}{3} π ) [ \begin{matrix}{a}_{- 1} sin ( ω t + {ϕ}_{- 1} - \frac{2}{3} π ) ++ {a}_{5} sin ( 5 ω t + {ϕ}_{5} - \frac{2}{3} π ) + \\ {a}_{7} sin ( 7 ω t + {ϕ}_{7} + \frac{2}{3} π ) ++ {a}_{11} sin ( 11 ω t + {ϕ}_{11} - \frac{2}{3} π ) + \\ {a}_{13} sin ( 13 ω t + {ϕ}_{13} + \frac{2}{3} π ) + O ( f \geq 17 \cdot {f}_{0} )\end{matrix} ] \\ 3 {x}_{d}^{0} ( t ) = {a}_{1} [ \begin{matrix}sin ( 2 ω t + {ϕ}_{1} ) + \\ sin ( {ϕ}_{1} )\end{matrix} ] + {a}_{- 1} [ \begin{matrix}sin ( 2 ω t + {ϕ}_{- 1} ) + \\ sin ( {ϕ}_{- 1} )\end{matrix} ] ++ {a}_{5} [ \begin{matrix}sin ( 6 ω t + {ϕ}_{5} ) + \\ sin ( 4 ω t + {ϕ}_{5} )\end{matrix} ] + {a}_{7} [ \begin{matrix}sin ( 8 ω t + {ϕ}_{7} ) + \\ sin ( 6 ω t + {ϕ}_{7} )\end{matrix} ] ++ {a}_{11} [ \begin{matrix}sin ( 12 ω t + {ϕ}_{11} ) + \\ sin ( 10 ω t + {ϕ}_{11} )\end{matrix} ] + {a}_{13} [ \begin{matrix}sin ( 14 ω t + {ϕ}_{13} ) + \\ sin ( 12 ω t + {ϕ}_{13} )\end{matrix} ] ++ O ( f \geq 16 \cdot {f}_{0} ) ++ {a}_{1} [ \begin{matrix}sin ( 2 ω t + {ϕ}_{1} - \frac{4}{3} π ) + \\ sin ( {ϕ}_{1} )\end{matrix} ] + {a}_{- 1} [ \begin{matrix}sin ( 2 ω t + {ϕ}_{- 1} ) + \\ sin ( {ϕ}_{- 1} + \frac{4}{3} π )\end{matrix} ] ++ {a}_{5} [ \begin{matrix}sin ( 6 ω t + {ϕ}_{5} ) + \\ sin ( 4 ω t + {ϕ}_{5} + \frac{4}{3} π )\end{matrix} ] + {a}_{7} [ \begin{matrix}sin ( 8 ω t + {ϕ}_{7} - \frac{4}{3} π ) + \\ sin ( 6 ω t + {ϕ}_{7} )\end{matrix} ] ++ {a}_{11} [ \begin{matrix}sin ( 12 ω t + {ϕ}_{5} ) + \\ sin ( 10 ω t + {ϕ}_{11} + \frac{4}{3} π )\end{matrix} ] + {a}_{13} [ \begin{matrix}sin ( 14 ω t + {ϕ}_{13} - \frac{4}{3} π ) + \\ sin ( 12 ω t + {ϕ}_{13} )\end{matrix} ] ++ O ( f \geq 16 \cdot {f}_{0} ) ++ {a}_{1} [ \begin{matrix}sin ( 2 ω t + {ϕ}_{1} + \frac{4}{3} π ) + \\ sin ( {ϕ}_{1} )\end{matrix} ] + {a}_{- 1} [ \begin{matrix}sin ( 2 ω t + {ϕ}_{- 1} ) + \\ sin ( {ϕ}_{- 1} - \frac{4}{3} π )\end{matrix} ] ++ {a}_{5} [ \begin{matrix}sin ( 6 ω t + {ϕ}_{5} ) + \\ sin ( 4 ω t + ϕ5 - \frac{4}{3} π )\end{matrix} ] + {a}_{7} [ \begin{matrix}sin ( 8 ω t + {ϕ}_{7} + \frac{4}{3} π ) + \\ sin ( 6 ω t + {ϕ}_{7} )\end{matrix} ] ++ {a}_{5} [ \begin{matrix}sin ( 6 ω t + {ϕ}_{5} ) + \\ sin ( 4 ω t + {ϕ}_{5} - \frac{4}{3} π )\end{matrix} ] + {a}_{7} [ \begin{matrix}sin ( 8 ω t + {ϕ}_{7} + \frac{4}{3} π ) + \\ sin ( 6 ω t + {ϕ}_{7} )\end{matrix} ] ++ O ( f \geq 10 \cdot {f}_{0} )$$

Similarly, a quadrature component x_{q}(t) may be produced according to the relation:

$$3 {x}_{q}^{0} ( t ) = - {a}_{1} sin ( ω t ) sin ( ω t + {ϕ}_{1} ) - sin ( ω t ) [ \begin{matrix}{a}_{- 1} sin ( ω t + {ϕ}_{- 1} ) ++ {a}_{5} sin ( 5 ω t + {ϕ}_{5} ) + \\ {a}_{7} sin ( 7 ω t + {ϕ}_{7} ) ++ {a}_{11} sin ( 11 ω t + {ϕ}_{11} ) + \\ {a}_{13} sin ( 13 ω t + {ϕ}_{7} ) + O ( f \geq 17 \cdot {f}_{0} )\end{matrix} ] -- {a}_{1} sin ( ω t - \frac{2}{3} π ) sin ( ω t + {ϕ}_{1} - \frac{2}{3} π ) - sin ( ω t - \frac{2}{3} π )$$

$$[ \begin{matrix}{a}_{- 1} sin ( ω t + {ϕ}_{- 1} + \frac{2}{3} π ) ++ {a}_{5} sin ( 5 ω t + {ϕ}_{5} + \frac{2}{3} π ) + \\ {a}_{7} sin ( 7 ω t + {ϕ}_{7} - \frac{2}{3} π ) ++ {a}_{11} sin ( 11 ω t + {ϕ}_{11} + \frac{2}{3} π ) + \\ {a}_{13} sin ( 13 ω t + {ϕ}_{13} - \frac{2}{3} π ) + O ( f \geq 17 \cdot {f}_{0} )\end{matrix} ] -- {a}_{1} sin ( ω t + \frac{2}{3} π ) sin ( ω t + {ϕ}_{1} + \frac{2}{3} π ) - sin ( ω t + \frac{2}{3} π ) [ \begin{matrix}{a}_{- 1} sin ( ω t + {ϕ}_{- 1} - \frac{2}{3} π ) ++ {a}_{5} sin ( 5 ω t + {ϕ}_{5} - \frac{2}{3} π ) + \\ {a}_{7} sin ( 7 ω t + {ϕ}_{7} + \frac{2}{3} π ) ++ {a}_{11} sin ( 11 ω t + {ϕ}_{11} - \frac{2}{3} π ) + \\ {a}_{13} sin ( 13 ω t + {ϕ}_{13} + \frac{2}{3} π ) + O ( f \geq 17 \cdot {f}_{0} )\end{matrix} ]$$

Similarly, the quadrature component x_{q}(t) may be somewhat simplified by use of the formula:

$$sin ( γ ) sin ( θ ) = \frac{1}{2} [ cos ( θ - γ ) - cos ( θ + y ) ] ,$$

resulting in

$$3 {x}_{q}^{0} ( t ) = {a}_{1} [ \begin{matrix}cos ( 2 ω t + {ϕ}_{1} ) - \\ cos ( {ϕ}_{1} )\end{matrix} ] + {a}_{- 1} [ \begin{matrix}cos ( 2 ω t + {ϕ}_{- 1} ) - \\ cos ( {ϕ}_{- 1} )\end{matrix} ] ++ {a}_{5} [ \begin{matrix}cos ( 6 ω t + {ϕ}_{5} ) - \\ cos ( 4 ω t + {ϕ}_{5} )\end{matrix} ] + {a}_{7} [ \begin{matrix}cos ( 8 ω t + {ϕ}_{7} ) - \\ cos ( 6 ω t + {ϕ}_{7} )\end{matrix} ] ++ {a}_{11} [ \begin{matrix}cos ( 12 ω t + {ϕ}_{11} ) - \\ cos ( 10 ω t + {ϕ}_{11} )\end{matrix} ] + {a}_{13} [ \begin{matrix}cos ( 14 ω t + {ϕ}_{13} ) - \\ cos ( 12 ω t + {ϕ}_{13} )\end{matrix} ] ++ O ( f \geq 16 \cdot {f}_{0} ) ++ {a}_{1} [ \begin{matrix}cos ( 2 ω t + {ϕ}_{1} - \frac{4}{3} π ) - \\ cos ( {ϕ}_{1} )\end{matrix} ] + {a}_{- 1} [ \begin{matrix}cos ( 2 ω t + {ϕ}_{- 1} ) - \\ cos ( {ϕ}_{- 1} + \frac{4}{3} π )\end{matrix} ] ++ {a}_{5} [ \begin{matrix}cos ( 6 ω t + {ϕ}_{5} ) - \\ cos ( 4 ω t + {ϕ}_{5} + \frac{4}{3} π )\end{matrix} ] + {a}_{7} [ \begin{matrix}cos ( 8 ω t + {ϕ}_{7} - \frac{4}{3} π ) - \\ cos ( 6 ω t + {ϕ}_{7} )\end{matrix} ] ++ {a}_{11} [ \begin{matrix}cos ( 12 ω t + {ϕ}_{11} ) - \\ cos ( 10 ω t + {ϕ}_{11} + \frac{4}{3} π )\end{matrix} ] + {a}_{13} [ \begin{matrix}cos ( 14 ω t + {ϕ}_{13} - \frac{4}{3} π ) - \\ cos ( 12 ω t + {ϕ}_{13} )\end{matrix} ] ++ O ( f \geq 16 \cdot {f}_{0} ) ++ {a}_{1} [ \begin{matrix}cos ( 2 ω t + {ϕ}_{1} + \frac{4}{3} π ) - \\ cos ( {ϕ}_{1} )\end{matrix} ] + {a}_{- 1} [ \begin{matrix}cos ( 2 ω t + {ϕ}_{- 1} ) - \\ cos ( {ϕ}_{- 1} - \frac{4}{3} π )\end{matrix} ] ++ {a}_{5} [ \begin{matrix}cos ( 6 ω t + {ϕ}_{5} ) - \\ cos ( 4 ω t + {ϕ}_{5} - \frac{4}{3} π )\end{matrix} ] + {a}_{7} [ \begin{matrix}cos ( 8 ω t + {ϕ}_{7} + \frac{4}{3} π ) - \\ cos ( 6 ω t + {ϕ}_{7} )\end{matrix} ] ++ {a}_{11} [ \begin{matrix}cos ( 12 ω t + {ϕ}_{11} ) - \\ cos ( 10 ω t + {ϕ}_{11} - \frac{4}{3} π )\end{matrix} ] + {a}_{13} [ \begin{matrix}cos ( 14 ω t + {ϕ}_{13} + \frac{4}{3} π ) - \\ cos ( 12 ω t + {ϕ}_{13} )\end{matrix} ] ++ O ( f \geq 16 \cdot {f}_{0} )$$

With further simplification the x_{d}(t) component and the x_{q}(t) component can be expressed as:

x_{d}⁰(t)=a₁ sin(ψ₁)+a₋₁ sin(2ωt+ψ₋₁)+a₅ sin(6ωt+ψ₅)+a₇ sin(6ωt+ψ₇)+

+a₁₁ sin(12ωt+ψ₁₁)+a₁₃ sin(12ωt+ψ₁₃)+O(f≧16·f₀)

x_{d}⁰(t)=a₁ cos(ψ₁)+a₋₁ cos(2ωt+ψ₋₁)+a₅ cos(6ωt+ψ₅)+a₇ cos(6ωt+ψ₇)+

+a₁₁ cos(12ωt+ψ₁₁)+a₁₃ cos(12ωt+ψ₁₃)+O(f≧16·f₀)

Thus it can be seen that as a result of the Blondel-Park transformation, a DC component and 2^{nd}, 6^{th} and 12^{th} harmonics are present in the x_{d}(t) and x_{q}(t) components produced by the transformation, which correspond respectively to the fundamental, the negative sequence (−1) and the 5^{th}, 7^{th}, 11^{th} and 13^{th} harmonics present in the input voltages x_{A}(t), x_{B}(t) and x_{C}(t). The apparatus further cancels these components by further processing as described below.

Cancellation of the 2^{nd}, 6^{th} and 12^{th} Harmonics

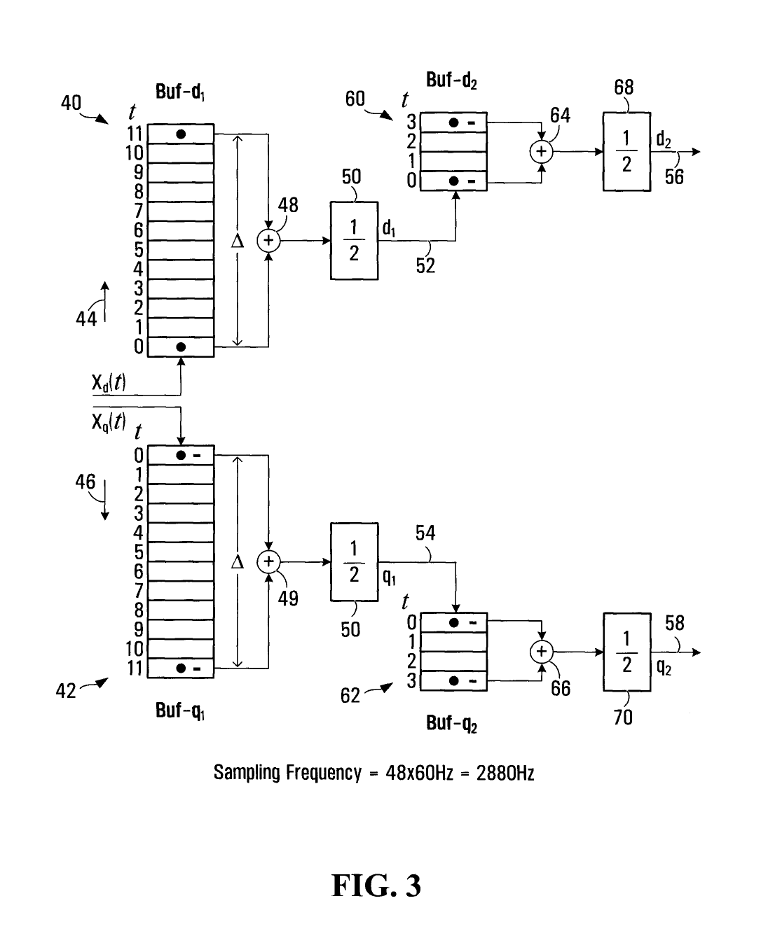

According to one embodiment of the invention, further processing to cancel the 2^{nd}, 6^{th} and 12^{th} harmonics resulting from the Blondel-Park Transformation involves storing successive ones of the two-axis rotating reference frame representation and summing particular ones of the successive ones of the two-axis rotating reference frame representation. This may involve storing the two-axis rotating reference frame representations in a first-in-first-out buffer and separately summing a component of a two-axis rotating reference frame representation associated with time t, with a corresponding component of a two-axis rotating reference frame representation associated with time t-Δ₁, to produce a first suppressed harmonic representation of the component of the two-axis rotating reference frame representation. For example, referring to FIG. 3, the x_{d}(t) produced by the Blondel-Park Transformation and the x_{q}(t) produced by the same transformation are stored in first and second FIFO buffers 40 and 42 respectively. Values in the buffers or pointers are shifted in the direction of arrows 44 and 46 each time a sample is taken and a new value is added so that x_{d}(t) and x_{q}(t) values are accumulated in respective buffers. With these values stored in respective buffers portions of the waveforms represented by the values stored in the buffers are added together as shown at 48 and 49 to effect canceling of certain harmonics.

For example, since the values in the buffers or pointers are shifted each time a sample is taken and a new value is added, a portion of a sampled waveform representing x_{d}(t) and x_{q}(t) is stored in each buffer. In the embodiment shown, the fundamental frequency of the electrical entity is 60 Hz and the sampling frequency is 48×60 Hz=2.88 kHz with a sampling period of 347 μSec. A sample acquired Δ sample periods (i.e., at t₁₁) before the present time t₀ is added to the sample at the present time. By causing the Δ sample periods to be equal to a multiple of the fundamental frequency of the two-axis rotating reference frame representation, a delayed version or “phase shifted” version of the waveform is added to the present version of the waveform and scaled as shown at 50 to produce first suppressed harmonic representations 52 and 54 of the components of the two-axis rotating reference frame representation. If the phase shift caused by the time delay of Δ sample periods is an odd multiple of π, for example, such that ωτ₁= (2n+1)π, where (n=0, 1, 2, 3, . . . , etc.), the corresponding component is suppressed or “trapped”. For example, if τ₁ is ¼ of the fundamental frequency of the electrical entity, i.e.

$${τ}_{1} = \frac{1}{4} \cdot \frac{2 π}{{ω}_{0}} ,$$

then

X_{dq}⁰(t,2ω₀)=−X_{dq}⁰(t−τ₁,2ω₀), and

X_{dq}⁰(t,6ω₀)=−X_{dq}⁰(t−τ₁,6ω₀).

Expanding, this may be represented as:

$$\begin{matrix}{X}_{dq}^{1} ( t ) = \frac{1}{2} [ {X}_{dq}^{0} ( t ) + {X}_{dq}^{0} ( t - {τ}_{1} ) ] \\ = \frac{1}{2} \{ \begin{matrix}{a}_{1} ( \begin{matrix}[ \begin{matrix}sin ( {ϕ}_{1} ( t ) ) \\ - cos ( {ϕ}_{1} ( t ) )\end{matrix} ] + \\ [ \begin{matrix}sin ( {ϕ}_{1} ( t - {τ}_{1} ) ) \\ - cos ( {ϕ}_{1} ( t - {τ}_{1} ) )\end{matrix} ]\end{matrix} ) ++ \\ {a}_{- 1} ( \begin{matrix}[ \begin{matrix}sin ( 2 ω t + {ϕ}_{- 1} ) \\ cos ( 2 ω t + {ϕ}_{- 1} )\end{matrix} ] + \\ [ \begin{matrix}sin ( 2 ω ( t - {τ}_{1} ) + {ϕ}_{- 1} ) \\ cos ( 2 ω ( t - {τ}_{1} ) + {ϕ}_{- 1} )\end{matrix} ]\end{matrix} ) ++ \\ {a}_{5} ( \begin{matrix}[ \begin{matrix}sin ( 6 ω t + {ϕ}_{5} ) \\ cos ( 6 ω t + {ϕ}_{5} )\end{matrix} ] + \\ [ \begin{matrix}sin ( 6 ω ( t - {τ}_{1} ) + {ϕ}_{5} ) \\ cos ( 6 ω ( t - {τ}_{1} ) + {ϕ}_{5} )\end{matrix} ]\end{matrix} ) ++ \\ {a}_{7} ( \begin{matrix}[ \begin{matrix}sin ( 6 ω t + {ϕ}_{7} ) \\ - cos ( 6 ω t + {ϕ}_{7} )\end{matrix} ] + \\ [ \begin{matrix}sin ( 6 ω ( t - {τ}_{1} ) + {ϕ}_{7} ) \\ - cos ( 6 ω ( t - {τ}_{1} ) + {ϕ}_{7} )\end{matrix} ]\end{matrix} ) ++ \\ {a}_{11} ( \begin{matrix}[ \begin{matrix}sin ( 12 ω t + {ϕ}_{11} ) \\ cos ( 12 ω t + {ϕ}_{11} )\end{matrix} ] + \\ [ \begin{matrix}sin ( 12 ω ( t - {τ}_{1} ) + {ϕ}_{11} ) \\ cos ( 12 ω ( t - {τ}_{1} ) + {ϕ}_{11} )\end{matrix} ]\end{matrix} ) ++ \\ {a}_{13} ( \begin{matrix}[ \begin{matrix}sin ( 12 ω t + {ϕ}_{13} ) \\ - cos ( 12 ω t + {ϕ}_{13} )\end{matrix} ] + \\ [ \begin{matrix}sin ( 12 ω ( t - {τ}_{1} ) + {ϕ}_{13} ) \\ - cos ( 12 ω ( t - {τ}_{1} ) + {ϕ}_{13} )\end{matrix} ]\end{matrix} )\end{matrix} \} + \\ O ( f \geq 16 \cdot {f}_{0} ) \}\end{matrix}$$

And further transforming into:

$$= \frac{1}{2} \{ \begin{matrix}{a}_{1} ( \begin{matrix}[ \begin{matrix}sin ( {ϕ}_{1} ( t ) ) \\ - cos ( {ϕ}_{1} ( t ) )\end{matrix} ] + \\ [ \begin{matrix}sin ( {ϕ}_{1} ( t - {τ}_{1} ) ) \\ - cos ( {ϕ}_{1} ( t - {τ}_{1} ) )\end{matrix} ]\end{matrix} ) + \\ {a}_{- 1} ( \begin{matrix}[ \begin{matrix}sin ( 2 ω t + {ϕ}_{- 1} ) \\ cos ( 2 ω t + {ϕ}_{- 1} )\end{matrix} ] + \\ [ \begin{matrix}sin ( 2 ω t - 2 ω \frac{1}{4} \cdot \frac{2 π}{{ω}_{0}} + {ϕ}_{- 1} ) \\ cos ( 2 ω t - 2 ω \frac{1}{4} \cdot \frac{2 π}{{ω}_{0}} + {ϕ}_{- 1} )\end{matrix} ]\end{matrix} ) ++ \\ {a}_{5} ( \begin{matrix}[ \begin{matrix}sin ( 6 ω t + {ϕ}_{5} ) \\ cos ( 6 ω t + {ϕ}_{5} )\end{matrix} ] + \\ [ \begin{matrix}sin ( 6 ω t - 6 ω \frac{1}{4} \cdot \frac{2 π}{{ω}_{0}} + {ϕ}_{5} ) \\ cos ( 6 ω t - 6 ω \frac{1}{4} \cdot \frac{2 π}{{ω}_{0}} + {ϕ}_{5} )\end{matrix} ]\end{matrix} ) ++ \\ {a}_{7} ( \begin{matrix}[ \begin{matrix}sin ( 6 ω t + {ϕ}_{7} ) \\ - cos ( 6 ω t + {ϕ}_{7} )\end{matrix} ] + \\ [ \begin{matrix}sin ( 6 ω t - 6 ω \frac{1}{4} \cdot \frac{2 π}{{ω}_{0}} + {ϕ}_{7} ) \\ - cos ( 6 ω t - 6 ω \frac{1}{4} \cdot \frac{2 π}{{ω}_{0}} + {ϕ}_{7} )\end{matrix} ]\end{matrix} ) ++ \\ {a}_{11} ( \begin{matrix}[ \begin{matrix}sin ( 12 ω t + {ϕ}_{11} ) \\ cos ( 12 ω t + {ϕ}_{11} )\end{matrix} ] + \\ [ \begin{matrix}sin ( 12 ω t - 12 ω \frac{1}{4} \cdot \frac{2 π}{{ω}_{0}} + {ϕ}_{11} ) \\ cos ( 12 ω t - 12 ω \frac{1}{4} \cdot \frac{2 π}{{ω}_{0}} + {ϕ}_{11} )\end{matrix} ]\end{matrix} ) ++ \\ {a}_{13} ( \begin{matrix}[ \begin{matrix}sin ( 12 ω t + {ϕ}_{13} ) \\ - cos ( 12 ω t + {ϕ}_{13} )\end{matrix} ] + \\ [ \begin{matrix}sin ( 12 ω t - 12 ω \frac{1}{4} \cdot \frac{2 π}{{ω}_{0}} + {ϕ}_{13} ) \\ - cos ( 12 ω t - 12 ω \frac{1}{4} \cdot \frac{2 π}{{ω}_{0}} + {ϕ}_{13} )\end{matrix} ]\end{matrix} )\end{matrix} \} ++ O ( f \geq 16 \cdot {f}_{0} ) \} \\ = {a}_{1} [ \begin{matrix}sin ( {ϕ}_{1} ) \\ - cos ( {ϕ}_{1} )\end{matrix} ] + {a}_{11} [ \begin{matrix}sin ( 12 ω t + {ϕ}_{11} ) \\ cos ( 12 ω t + {ϕ}_{11} )\end{matrix} ] + {a}_{13} [ \begin{matrix}sin ( 12 ω t + {ϕ}_{13} ) \\ - cos ( 12 ω t + {ϕ}_{13} )\end{matrix} ] ++ O ( f \geq 16 \cdot {f}_{0} )$$

$$with ω = {ω}_{0} and {ϕ}_{1} ( t - {τ}_{1} ) = {ϕ}_{1} ( t )$$

As can be seen from the final line above, only the DC component and the 12^{th} harmonic and some other relatively insignificant harmonics greater than or equal to the 16^{th} harmonic remain, which correspond respectively to the fundamental frequency component, the 11^{th} and 13^{th} harmonics and higher order harmonics present in the input three-phase voltages x_{A}(t), x_{B}(t) and x_{C}(t). As a result, the 2^{nd} and 6^{th} harmonics of the fundamental frequency of the two-axis rotating reference frame representation are suppressed. This means that the contributions of the −1, 5^{th}, 7^{th}, harmonics of the fundamental frequency of the electrical entity are effectively suppressed.

The method further involves canceling contributions of harmonics included in the first suppressed harmonic representations 52 and 54 to produce second suppressed harmonic representations 56 and 58 respectively. To do this, successive ones of the first suppressed harmonic representation are stored. In one embodiment, successive ones of the x_{d}(t) and x_{q}(t) components are stored in respective buffers 60 and 62. As shown at 64 and 66 value at time t is added to a value at time t-Δ₂ to produce the second suppressed harmonic representation of the two-axis rotating reference frame representation. This is done for each component x_{d}(t) and x_{q}(t). A scaling is then performed as shown at 68 and 70. By the same reasoning above, if Δ₂ is 1/24 of the fundamental frequency, then

X_{dq}⁰(t,12ω₀)=−X_{dq}⁰(t−Δ₂,12ω₀)

As a result, the 12^{th} and other, higher order harmonics of the fundamental frequency of the two-axis rotating reference frame representation are suppressed. This means that the contributions of the 11^{th} and 13^{th}, and some insignificant higher order harmonics of the fundamental frequency of the electrical entity are effectively suppressed. As a result, all contributions of the significant harmonics of the fundamental frequency are cancelled from the two-axis rotating reference frame representation, leaving virtually only the contribution of the fundamental frequency of the electrical entity and therefore a relatively accurate two-axis rotating reference frame representation of the status of the power system.

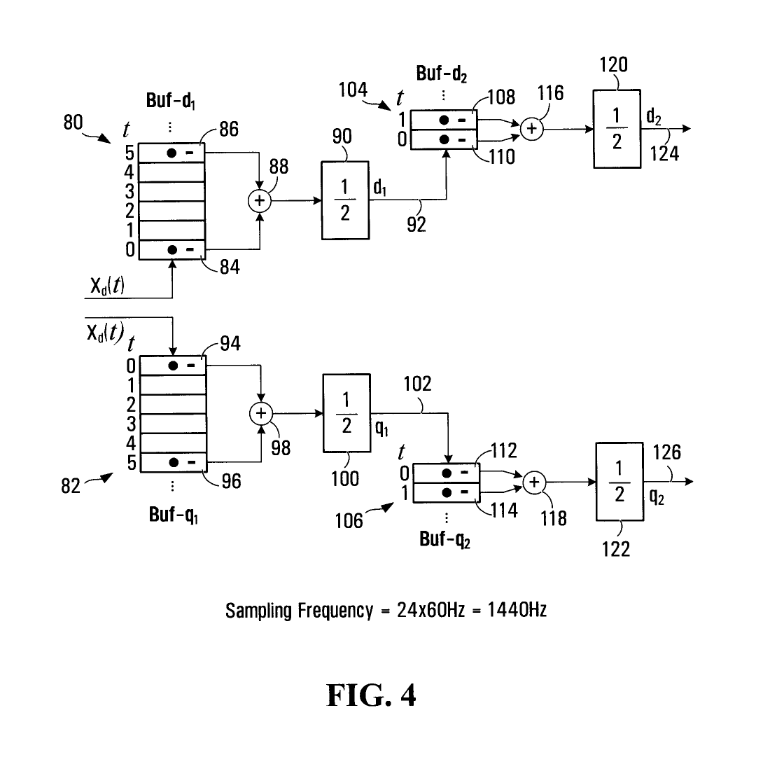

Referring to FIG. 4, in an alternative embodiment, buffer depths can be reduced where the sampling frequency is reduced. For example, if the sampling frequency is 24×60 Hz, the desired effect of canceling harmonics can be achieved by shifting the x_{d}(t) and x_{q}(t) values produced by the Blondel-Park Transformation into respective buffers 80 and 82, which are only 6 locations deep. The contents of the first and sixth locations 84 and 86 are added together as shown at 88 and scaled as shown at 90, for example, to produce a first suppressed harmonic representation 92 for the x_{d}(t) component of the two-axis rotating reference frame representation. Similarly, for the x_{q}(t) component, the first and sixth buffer locations 94 and 96 are added together as shown at 98 and scaled as shown at 100 to produce a first suppressed harmonic component 102 of the x component of the rotating reference frame representation. These x_{d}(t) and x_{q}(t) components 92 and 102 of the first suppressed harmonic component representation are stored in buffers 104 and 106 respectively, and the first and second locations 108, 110 and 112, 114 of each buffer are added together as shown at 116 and 118 and then scaled as shown at 120 and 122 to produce the second suppressed harmonic representation of the two-axis rotating reference frame representation as shown at 124 and 126 respectively.

Referring to FIG. 3, the x_{d}(t) and x_{q}(t) components of the second suppressed harmonic representation provide the clean two-axis rotating reference frame representation of the virtual rotor position associated with the electrical entity measured by the apparatus. In FIG. 4, the x_{d}(t) and x_{q}(t) components 124 and 126 of the second suppressed harmonic representation act as the clean two-axis rotating reference frame representation of the virtual rotor position for the measured electrical entity. A virtual rotor angle, for example, can be obtained by taking the inverse tangent of the x_{q}(t) component divided by the x_{d}(t) component. This angle can be associated with a time stamp which may be produced each time a sample is taken, and the time stamp and the virtual rotor angle can be forwarded to the monitoring station 18 for analysis. Alternatively, the second suppressed harmonic representation provided by components 124 and 126 may be associated with a time stamp and sent to the monitoring station 18.

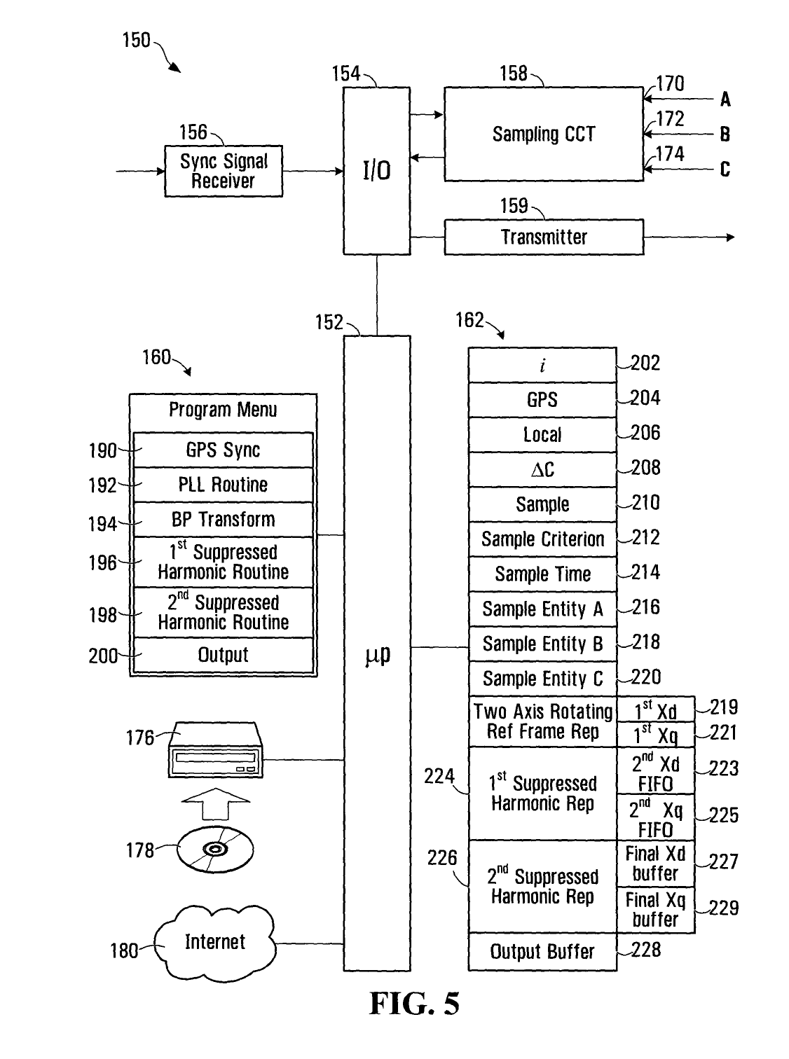

Referring to FIG. 5, an apparatus for producing a phasor representation of an electrical entity at a geographical location in a multiple phase AC electric power system is shown generally at 150. In this embodiment, the apparatus includes a processor 152, an I/O port 154, a synch signal receiver 156, a sampling circuit 158, program memory shown generally at 160, and random access memory shown generally at 162. The program memory 160 and random access memory 162 and the I/O port 154 are in communication with the microprocessor. The synch signal receiver 156, the sampling circuit 158, and the transmitter 159 are in communication with the I/O port 154.

The synch signal receiver 156 is operable to receive the synchronization signal from the remote source. As mentioned above, the remote source may be a GPS system or more particularly, a GPS satellite that provides a count value in microseconds, every 1 second.

The sampling circuit 158 is operable to receive signals at inputs 170, 172, and 174, representing the electrical entity to be measured. Such signals may be conditioned signals received from a potential transformer or current transformer, for example, coupled to a transmission line. In response to a signal received from the I/O port 154, the sampling circuit takes a sample of each of the signals appearing at inputs 170, 172, and 174 to provide three numbers, each number representing an amplitude of the sampled signal received at the corresponding input. These three numbers are provided back to the I/O port 154 for communication to the microprocessor 152.

The processor 152 is controlled by codes stored in the program memory 160. Such codes may be burned onto a programmable read-only memory, for example, which acts as the program memory 160, or such codes may be received through a media interface such as shown at 176 for example, in communication with the microprocessor 152 for receiving the codes on a computer-readable medium 178 such as a CD-Rom, for example.

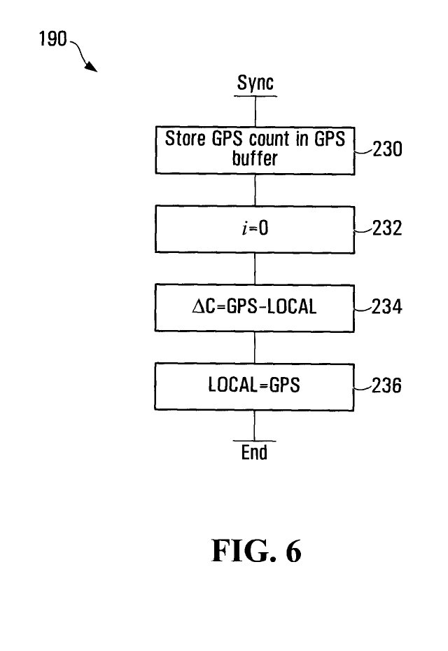

Alternatively, or in addition, the processor may be connected to a network interface 180 for receiving a signal encoded with codes for directing the processor to carry out the method described above, or variations thereof. In the embodiment shown, aside from the usual basic operating system code required by the processor 152, the program memory is encoded with codes that provide a GPS synch routine 190, a phase locked loop routine 192, a Blondel-Park Transform routine 194, a first suppressed harmonic routine 196, a second suppressed harmonic routine 198, and an output routine 200. These routines establish or use a data structure stored in the random access memory 162 and having a counter variable 202, a GPS variable 204, a local variable 206, a Δ count value 208, a sample value 210, a sample criterion value 212, a sample time buffer 214, a sampled entity A buffer 216, a sampled entity B buffer 218, a sampled entity C buffer 220, a two-axis rotating reference frame buffer 222, comprising a first x_{d}(t) FIFO 219 and a first x_{q}(t) FIFO 221, a first suppressed harmonic representation buffer 224, comprising 2^{nd} x_{d}(t) FIFO 223 and a 2^{nd} x_{q}(t) FIFO 225 a second suppressed harmonic representation buffer 226, comprising a final x_{d}(t) buffer 227 and a final x_{q}(t) buffer 229 and an output buffer 228. Referring to FIGS. 6, 7, 8, 9, 10, and 11, the cooperation between the routines shown at 190-200 with the data structure and its components shown at 202-228 will be explained.

Referring to FIGS. 5 and 6, the GPS synch routine is shown generally at 190 in FIG. 6. This routine is invoked each time a GPS synch signal is received at the synch signal receiver 156, from a GPS satellite, for example. Referring to FIG. 6, the routine beings with block 192 which causes the processor to store the current GPS count value received in the GPS synch signal, in the GPS buffer 204 shown in FIG. 5. Block 194 then directs the processor to set the contents of the counter variable 202 to 0. Block 196 then directs the processor to calculate a Δ count value 208 by subtracting the contents of the local variable 206 from the current contents of the GPS variable 204. Block 198 then directs the processor to set the contents of the local variable 206 equal to the contents of the GPS variable 204.

In effect, the GPS synch routine serves to reestablish values in the counter variable 202 and local variable 206 and to calculate a Δ count value representing a difference between a count value produced by the accurate GPS clock in the satellite of the GPS system and a count value produced locally at the apparatus.

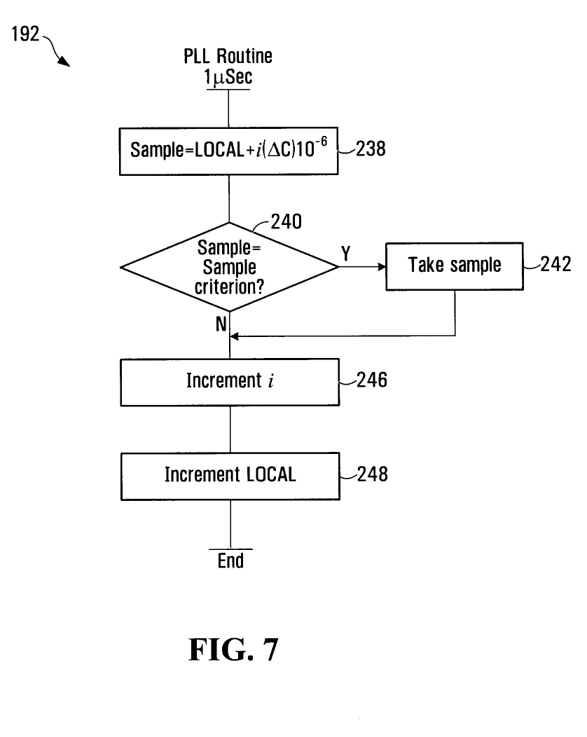

Referring to FIG. 7, the phase locked loop routine is shown generally at 192. This routine is invoked every 1 microsecond. In this regard, the processor 152 may have a built-in clock interrupt that causes an interrupt to occur every one microsecond, and when such interrupt occurs, the phase locked loop routine is executed.

The phase locked loop routine begins with a first block 238 at produces a sample count value for storage in the sample value 210 shown in FIG. 5 by adding the contents of the local value 206 to the product of the count variable 202, the Δ count value 208, and a scaling factor of 10⁻⁶.

Block 240 then directs the processor to determine whether or not the sample value 210 is equal to the sample criterion value 212 and if so, block 242 directs the processor to communicate with the I/O port 154 to cause the sampling circuit 158 to take samples of the three signals representing the three phases of the electrical entity being measured, received at inputs 170, 172, and 174 of the sampling circuit. The sampling circuit then passes back to the I/O port 154, which passes back to the processor 152, the sample values for storage in locations in the sampled entity buffers 216, 218, and 220, respectively. The sample entity buffers are essentially first-in first-out buffers for each of the values.

Referring back to FIG. 7, if the sample count value is not equal to the sample criterion value at block 240, or upon completion of acquisition of a sample at block 242, the processor is directed to block 246 which causes it to increment the contents of the counter variable 202. Block 248 then directs the processor to increment the contents of the local variable 206, and the phase locked loop routine is ended.

In effect, the phase locked loop routine increments the local variable 206 every one microsecond. At the same time it adds to the current contents of the local variable a correction value represented by the product term comprised of the count variable 202 and the Δ count value 208. This has the effect of adjusting the contents of the local variable 206 with an error correction value derived from the difference between the last received GPS count value and the contents of the local variable 206 at the time the last received GPS count value was received. This essentially makes a correction for differences between the accuracy of the one microsecond clock interrupt provided by the processor and the one microsecond incremented count value produced by the accurate GPS satellite clock. At the same time, block 240 continuously monitors the contents of the sample count value to determine whether or not it is time to take a sample. For example, if the sampling period is 347 μSec, the sample criterion value 212 would be set to 347 μSec and multiples thereof. Therefore, each time the sample value stored in location 210 reaches the value 347 or a multiple thereof block 242 would be invoked to cause a sample of the electrical entity being measured to be taken.

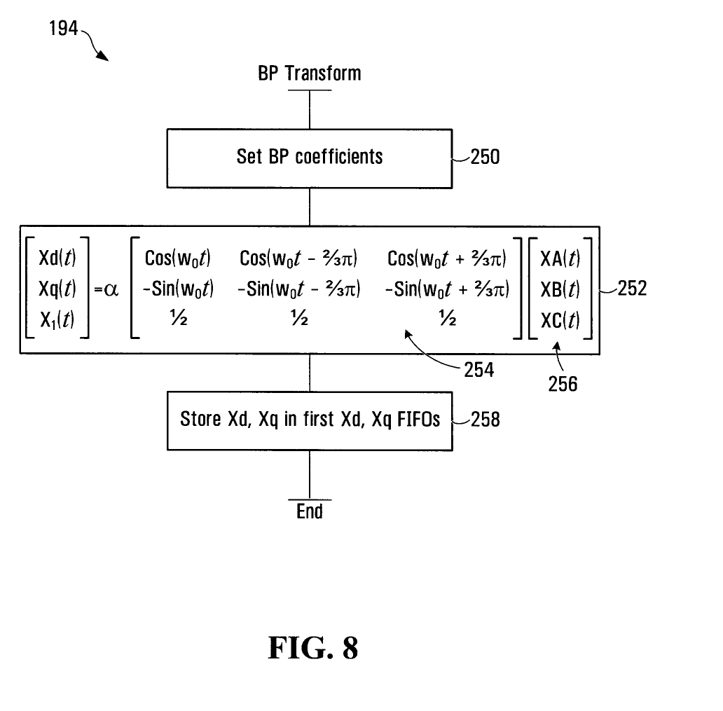

Referring to FIG. 8, the Blondel-Park Transform routine is shown generally at 194. This routine begins with a first block 250 which causes the processor to set Blondel-Park coefficients for use in the Blondel-Park Transform. The setting of the coefficients involves the setting of an angular rotation frequency coo and a sample time value t. Knowing these coefficients, cosine and sine values used in the transformation can be precomputed as absolute numbers before the transformation is executed. Similarly, a scaling component a is set. The scaling component a is generally a constant that may take different values for different applications, the value of which will not, however, affect phasor calculations.

After setting Blondel-Park coefficients at block 250, block 252 directs the processor to perform the Blondel-Park Transformation using a matrix shown generally at 254 produced using the Blondel-Park coefficients set at block 250 and a vector 256 representing sample values associated with phases A, B and C of the electrical entity at the sampling time. The result of the transformation is an x_{d}(t) value representing the direct component of the transformation, an x_{q}(t) representing a quadrature component of the transformation and an x₀(t) value representing a component that is not of interest in calculating a phasor or virtual rotor position and is therefore ignored.

After performing the Blondel-Park Transformation at block 252, block 258 directs the processor to store the x_{d}(t) and x_{q}(t) values in first x_{d}(t) and x_{q}(t) FIFOs 219 and 221, respectively.

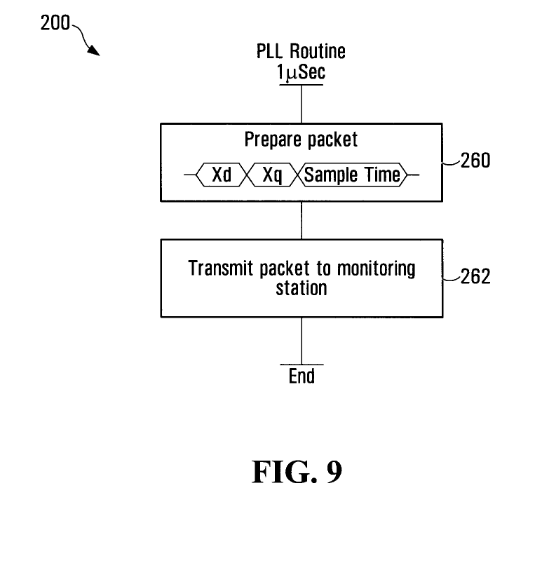

In a simple embodiment with no harmonic suppression, the output routine 200 may be executed immediately. The output routine is shown generally at 200 in FIG. 9, and includes a first block 260 that directs the processor to prepare an outgoing packet. To do this, the processor stores in a transmission output buffer (not shown) in the I/O port 154, the x_{d}(t) value stored in the FIFO 219 and the x_{q}(t) value stored in the FIFO 221, and a sample time value representing the time at which the sample was taken. This time value may be the contents of the sample count value 210, for example. Referring back to FIG. 9, block 262 then directs the processor to cause the packet prepared at block 260 to be transmitted by the transmitter 159 shown in FIG. 5, to the monitoring station 18 shown in FIG. 1.

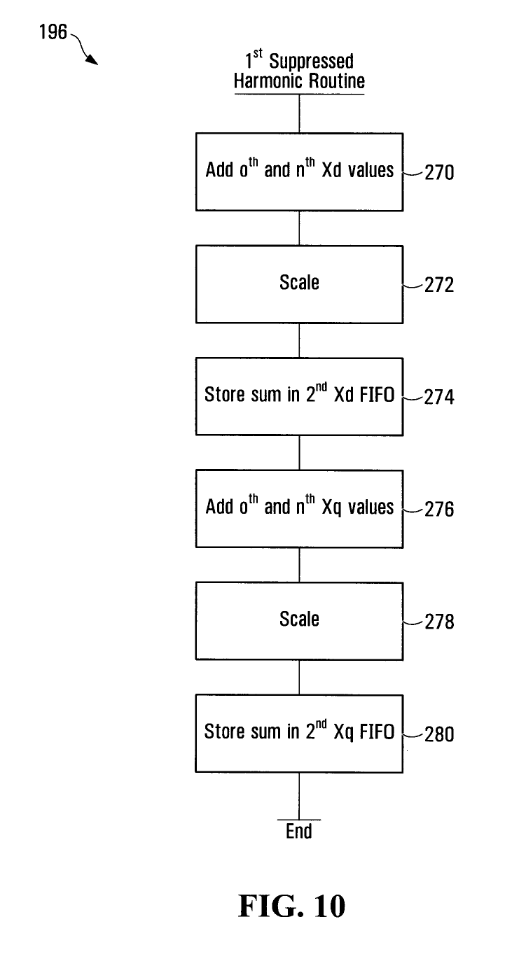

In an embodiment where certain harmonics are to be suppressed, the first suppressed harmonic routine 196 as shown in FIG. 10 is used to suppress the second and sixth harmonics included in the x_{d}(t) and x_{q}(t) values stored in the x_{d}(t) FIFO 219 and the x_{q}(t) FIFO 221, respectively. As stated above, the second harmonic corresponds to the negative sequence component of the electrical entity and the sixth harmonic of the x_{d}(t) and x_{q}(t) values corresponds to the fifth and seventh harmonics of the electrical entity.

Still referring to FIG. 10, the first suppressed harmonic routine begins with block 270 which causes the processor to add the 0^{th} and n^{th} x_{d}(t) values stored in the x_{d}(t) FIFO 219. Where the sampling frequency is 2880 Hz, for example, n=11. Referring to FIG. 3, block 270 corresponds to the addition block shown at 48 in FIG. 3. Referring back to FIG. 10, block 272 directs the processor to scale the result of the addition performed at block 270, such as by reducing the amplitude of the value by ½. Block 274 then directs the processor to store the scaled sum in the second x_{d}(t) FIFO buffer 223. Block 276 then directs the processor to add the 0^{th} and n^{th} x_{q}(t) values stored in the x_{q}(t) FIFO 221. Block 276 would correspond to the addition block shown at 49 in FIG. 3. Referring back to FIG. 10, block 278 directs the processor to scale the result of the addition performed at block 276, such as reducing the amplitude of the value by ½. Block 280 then directs the processor to store the scaled sum in the second x_{q}(t) FIFO buffer 225, and the process is ended. The contents that were just deposited in the second x_{d}(t) FIFO buffer 223 and second x_{q}(t) FIFO buffer 225 are x_{d}(t) and x_{q}(t) values of a first suppressed harmonic representation. The representation provided by these values is a representation in which the 2^{nd} and 6^{th} harmonics resulting from the Blondel-Park Transformation and, more importantly, the contributions due to the negative sequence and 5^{th} and 7^{th} harmonics of the electrical entity being measured are suppressed. This representation, however, still contains components including the 12^{th} harmonic of the two-axis rotating reference frame representation and some other relatively insignificant harmonics greater than or equal to the 16^{th} harmonic. The 12^{th} harmonic corresponds to the 11^{th} and 13^{th} harmonics in the electrical entity being measured. To suppress this 12^{th} harmonic, the second suppressed harmonic routine 198 is executed.

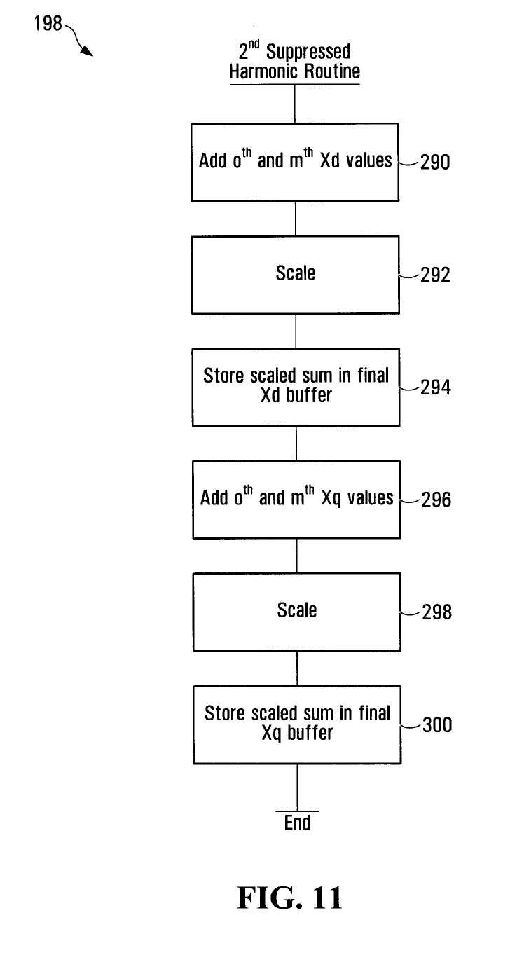

Referring to FIG. 11, the second suppressed harmonic routine is shown generally at 198 and begins with a first block 290 that directs the processor to add the 0^{th} and n^{th} x_{d}(t) values stored in the second x_{d}(t) FIFO 223. Where the sampling frequency is 2880 Hz n for this calculation is 3. The effect of block 290 is shown generally at 64 in FIG. 3. Referring back to FIG. 11, following the addition performed at block 290, block 292 directs the processor to scale the value produced by the addition, and block 294 directs the processor to store the scaled sum in the final x_{d}(t) buffer 227. Referring back to FIG. 11, block 296 directs the processor to add the 0^{th} and n^{th} x_{q}(t) values stored in the second x_{q}(t) FIFO 225, the equivalent of which is shown at 66 in FIG. 3. Block 298 then directs the processor to scale the results of the addition shown in block 296, and block 300 directs the processor to store the scaled sum in the final x_{q}(t) buffer 229. The x_{d}(t) value stored in the final x_{d}(t) buffer 227 and the final x_{q}(t) value stored in the final x_{q}(t) buffer 229 provide a second suppressed harmonic representation of the two-axis rotating reference frame representation which has been stripped of the 2^{nd}, 6^{th}, and 12^{th} harmonics of the two-axis rotating reference frame representation corresponding to the negative sequence, 5^{th}, 7^{th}, 11^{th}, and 13^{th} harmonics of the measured electrical entity. As discussed above, other harmonics remain, however such other harmonics are generally insignificant and can be ignored. Therefore the x_{d}(t) and x_{q}(t) values stored in the final x_{d}(t) and x_{q}(t) buffer 227 and 229 provide a clean two-axis rotating reference frame representation of phasor or virtual rotor position associated with the electrical entity being measured. Where the first suppressed harmonic routine shown in FIG. 10 and the second suppressed harmonic routine shown in FIG. 11 are used, the output routine shown in FIG. 9 prepares the packet as shown in block 260 in such a manner that the x_{d}(t) and x_{q}(t) values in the packet are copied from the final x_{d}(t) buffer 227 and the final x_{q}(t) buffer 229. A sample time such as the current contents of the sample value 210 is associated with these values as described above in connection with FIG. 9, and block 262 directs the processor to cause a packet comprising the clean x_{d}(t) and x_{q}(t) values and the sample time to be sent to the monitoring station 18.

As a result of the first and second suppressed harmonic routines, the apparatus sends to the monitoring station a clean phasor or representation of virtual rotor position free of any significant contribution of distortion due to harmonics. Therefore, the phasor or virtual rotor position is accurate with little percentage of error. Consequently, the phasor or virtual rotor position can be relied on more heavily by the monitoring station 18 and can be used for comparison with other virtual rotor positions produced in the same way, for example, to assist in assessing system stability.

While specific embodiments of the invention have been described and illustrated, such embodiments should be considered illustrative of the invention only and not as limiting the invention as construed in accordance with the accompanying claims.

What is claimed is:

1. An apparatus for producing a first phasor representation of an electrical
entity at a geographical location in a multiple phase AC electric power system, the apparatus comprising:
a receiver operably configured to receive a synchronization signal from a remote source;
a local reference time signal generator operably configured to generate a local reference time signal;
a sampling time signal generator operably configured to produce a sampling time signal in response to said synchronization signal and said local reference time signal;
a sampling circuit operably configured to produce samples representing an amount of said electrical entity in respective ones of said phases in said AC power system in response to said sampling time signal and said entity in respective ones of said phases in said AC power system;
a processor operably configured to perform a transformation on said samples to produce a two-axis rotating reference frame representation of said electrical entity in a two-axis rotating reference frame;
a time stamp generator operably configured to produce time stamps representing time at which respective said samples are taken by said sampling circuit;
wherein said two-axis rotating reference frame representation and said time stamp comprise said first phasor representation.

2. The apparatus of claim 1 wherein said receiver is operably configured to receive a synchronization signal that is also received by at least one other apparatus operable to produce a second phasor representation of an electrical entity at a different geographical location in said multiple phase AC electric power system.

3. The apparatus of claim 1 wherein said receiver is operably configured to receive a wirelessly transmitted synchronization signal.

4. The apparatus of claim 3 wherein said receiver is operably configured to receive a global positioning system (GPS) signal from a GPS system.

5. The apparatus of claim 1 wherein said sampling time signal generator comprises:
a) a counter incremented in response to said local reference time signal;
b) a circuit operably configured to determine a difference in counts between said counter incremented by said local reference time signal and a counter associated with said synchronization signal, in response to receipt of said synchronization signal;
c) a circuit operably configured to add to a count value produced by said counter incremented by said local reference time signal, a fraction of said difference in counts, to produce a sample count value; and
d) a circuit operably configured to cause a sample of said electrical entity to be produced when said sample count value satisfies a criterion.

6. The apparatus of claim 1 wherein said processor is operably configured to perform a Blondel-Park Transformation on said sampled signals.

7. The apparatus of claim 6 wherein said processor is operably configured to set transformation coefficients of said Blondel-Park Transformation in response to said sampling time signal and a frequency value representing a rotation frequency of said two-axis rotating reference frame.

8. The apparatus of claim 1 wherein said two-axis rotating reference frame representation comprises a direct axis component and a quadratic axis component.

9. The apparatus of claim 1 wherein said two-axis rotating reference frame representation comprises a modulus component and an angle component.

10. The apparatus of claim 1 wherein said processor is operably configured to cancel contributions of harmonics included in said two-axis rotating reference frame representation.

11. The apparatus of claim 10 wherein said processor is operably configured to store successive ones of said two-axis rotating reference frame representation and sum particular ones of said successive ones of said two-axis rotating reference frame representation.

12. The apparatus of claim 11 further comprising a first-in-first-out buffer in communication with said processor for storing said successive ones of said two-axis rotating reference frame representation.

13. The apparatus of claim 11 wherein said processor is operably configured to separately sum a component of a two-axis rotating reference frame representation associated with time t, with a component of a two-axis rotating reference frame representation associated with time t-Δ₁, to produce a first suppressed harmonic representation of said component of said two-axis rotating reference frame representation.

14. The apparatus of claim 13 wherein t-Δ₁ represents a time Δ₁ sample periods before time t.

15. The apparatus of claim 14 wherein Δ₁ represents ¼ of a period of a fundamental frequency of said electrical entity.

16. The apparatus of claim 13 further comprising a fundamental frequency signal generator in communication with said processor and operably configured to determine a fundamental frequency of said electrical entity and wherein said processor is operably configured to set Δ₁ in response to said fundamental frequency.

17. The apparatus of claim 13 wherein said processor is operably configured to cancel contributions of harmonics included in said first suppressed harmonic representation to produce a second suppressed harmonic representation.

18. The apparatus of claim 18 wherein said processor is operably configured to store successive ones of said first suppressed harmonic representation and sum particular ones of said successive ones of said first suppressed harmonic representation.

19. The apparatus of claim 18 further comprising a first-in-first-out buffer for storing said first suppressed harmonic representation.

20. The apparatus of claim 19 wherein said processor is operably configured to separately sum a component of a first suppressed harmonic representation associated with time t, with a component of a first suppressed harmonic representation associated with time t-Δ₂ to produce said second suppressed harmonic representation.

21. The apparatus of claim 20 wherein t-Δ₂ represents a time Δ₂ sample periods before time t.

22. The apparatus of claim 21 wherein Δ₂ represents 1/24 of a period of a fundamental frequency of said electrical entity.

23. The apparatus of claim 20 further comprising a fundamental frequency signal generator in communication with said processor and operably configured to determine a fundamental frequency of said electrical entity and wherein said processor is operably configured to set Δ₂ in response to said fundamental frequency.

24. A method of producing a first phasor representation of an electrical entity at a geographical location in a multiple phase AC electric power system, the method comprising:
receiving a synchronization signal from a remote source;
producing a sampling time signal in response to said synchronization signal and a local reference time signal;
producing samples representing an amount of said entity in respective ones of said phases in said AC power system in response to said sampling time signal and said electrical entity in respective ones of said phases in said AC power system;
performing a transformation on said samples to produce a two-axis rotating reference frame representation of said electrical entity in a two-axis rotating reference frame;
for each sample, producing a representation of a sampling time associated with said sample; and
wherein said two-axis rotating reference frame representation and said representation of said sampling time comprise said first phasor representation.

25. The method of claim 24 wherein receiving said synchronization signal comprises receiving a synchronization signal that is also received by at least one other apparatus operable to produce a second phasor representation of an electrical entity at a different geographical location in said multiple phase AC electric power system.

26. The method of claim 24 wherein receiving said synchronization signal comprises receiving a wirelessly transmitted synchronization signal.

27. The method of claim 26 wherein receiving said wirelessly transmitted synchronization signal comprises receiving a global positioning signal system (GPS) signal from a GPS system.

28. The method of claim 24 wherein producing said sampling time signal comprises determining a difference in counts between a counter incremented by the local reference time signal and a counter associated with said synchronization signal in response to receipt of said synchronization signal.

29. The method of claim 28 wherein producing said sampling time signal comprises adding to a count value produced by said counter incremented by said local reference time signal a fraction of said difference in counts to produce a sample count value and causing a sample of said entity to be produced when said sample count value satisfies a criterion.

30. The method of claim 24 wherein performing a transformation comprises performing a Blondel-Park Transformation on said sampled signals.

31. The method of claim 30 wherein performing a Blondel-Park transformation comprises setting transformation coefficients of said Blondel-Park Transformation in response to said sampling time signal and a frequency value representing a rotation frequency of said two-axis rotating reference frame.

32. The method of claim 24 wherein said two-axis rotating reference frame representation comprises a direct axis component and a quadratic axis component.

33. The method of claim 24 wherein said two-axis rotating reference frame representation comprises a modulus component and an angle component.

34. The method of claim 24 further comprising canceling contributions of harmonics included in said two-axis rotating reference frame representation.

35. The method of claim 34 wherein canceling contributions of harmonics comprises storing successive ones of said two-axis rotating reference frame representation and summing particular ones of said successive ones of said two-axis rotating reference frame representation.

36. The method of claim 35 wherein storing said successive ones of said two-axis rotating reference frame representation comprises storing said two-axis rotating reference frame representations in a first-in-first-out buffer.

37. The method of claim 35 wherein summing particular ones of said successive ones of said two-axis rotating reference frame representation comprises separately summing a component of a two-axis rotating reference frame representation associated with time t, with a component of a two-axis rotating reference frame representation associated with time t-Δ₁, to produce a first suppressed harmonic representation of said component of said two-axis rotating reference frame representation.

38. The method of claim 37 wherein t-Δ₁ represents a time Δ₁ sample periods before time t.

39. The method of claim 37 wherein Δ₁ represents ¼ of a cycle of a fundamental frequency of said electrical entity.

40. The method of claim 37 further comprising determining a fundamental frequency of said electrical entity and setting Δ₁ in response to said fundamental frequency.

41. The method of claim 36 further comprising canceling contributions of harmonics included in said first suppressed harmonic representation to produce a second suppressed harmonic representation.

42. The method of claim 41 wherein canceling contributions of harmonics comprises storing successive ones of said first suppressed harmonic representation and summing particular ones of said successive ones of said first suppressed harmonic representation.

43. The method of claim 42 wherein storing successive ones of said first suppressed harmonic representation comprises storing said first suppressed harmonic representation in a first-in-first-out buffer.

44. The method of claim 43 wherein summing particular ones of said successive ones of said first suppressed harmonic representation comprises separately summing a component of a first suppressed harmonic representation associated with time t, with a component of a first suppressed harmonic representation associated with time t-Δ₂ to produce said second suppressed harmonic representation of said two-axis rotating reference frame representation.

45. The method of claim 44 wherein t-Δ₂ represents a time Δ₂ sample periods before time t.

46. The method of claim 45 wherein Δ₂ represents 1/24 of a period of a fundamental frequency of said electrical entity.

47. The method of claim 44 further comprising determining a fundamental frequency of said electrical entity and setting Δ₂ in response to said fundamental frequency.

48. An apparatus for producing a first phasor representation of an electrical entity at a geographical location in a multiple phase AC electric power system, the apparatus comprising:
means for receiving a synchronization signal from a remote source;
means for producing a sampling time signal in response to said synchronization signal and a local reference time signal;
means for producing samples representing an amount of said entity in respective ones of said phases in said AC power system in response to said sampling time signal and said electrical entity in respective ones of said phases in said AC power system;
means for performing a transformation on said samples to produce a two-axis rotating reference frame representation of said electrical entity in a two-axis rotating reference frame;
means for producing a representation of a sampling time associated with respective said samples;
wherein said two-axis rotating reference frame representation and said representation of said sampling time comprise said first phasor representation.

49. The apparatus of claim 48 wherein receiving said synchronization signal comprises receiving a synchronization signal that is also received by at least one other apparatus operable to produce a second phasor representation of an electrical entity at a different geographical location in said multiple phase AC electric power system.

50. The apparatus of claim 48 wherein said means for receiving said synchronization signal comprises means for receiving a wirelessly transmitted synchronization signal.

51. The apparatus of claim 50 wherein said means for receiving said wirelessly transmitted synchronization signal comprises means for receiving a Global Positioning System (GPS) signal from a GPS system.

52. The apparatus of claim 48 wherein said means for producing said sampling time signal comprises:
a) a counter incremented by a local clock signal;
b) means for determining a difference in counts between said counter incremented by said local reference time signal and a counter associated with said synchronization signal, in response to receipt of said synchronization signal.

53. The apparatus of claim 52 wherein said means for producing said sampling time signal comprises means for adding to a count value produced by said counter incremented by said local reference time signal a fraction of said difference in counts to produce a sample count value and for causing a sample of said entity to be produced when said sample count value satisfies a criterion.

54. The apparatus of claim 48 wherein said means for performing a transformation comprises means for performing a Blondel-Park Transformation on said sampled signals.

55. The apparatus of claim 54 wherein said means for performing a Blondel-Park transformation comprises means for setting transformation coefficients of said Blondel-Park Transformation in response to said sampling time signal and a frequency value representing a rotation frequency of said two-axis rotating reference frame.

56. The apparatus of claim 48 wherein said two-axis rotating reference frame representation comprises a direct axis component and a quadratic axis component.

57. The apparatus of claim 48 wherein said two-axis rotating reference frame representation comprises a modulus component and an angle component.

58. The apparatus of claim 48 further comprising means for canceling contributions of harmonics included in said two-axis rotating reference frame representation.

59. The apparatus of claim 58 wherein said means for canceling contributions of harmonics comprises means for storing successive ones of said two-axis rotating reference frame representation and means for summing particular ones of said successive ones of said two-axis rotating reference frame representation.

60. The apparatus of claim 59 wherein said means for storing said successive ones of said two-axis rotating reference frame representation comprises a first-in-first out buffer for storing said two-axis rotating reference frame representations.

61. The apparatus of claim 59 wherein said means for summing particular ones of said successive ones of said two-axis rotating reference frame representation comprises means for separately summing a component of a two-axis rotating reference frame representation associated with time t, with a corresponding component of a two-axis rotating reference frame representation associated with time t-Δ₁, to produce a first suppressed harmonic representation of said component of said two-axis rotating reference frame representation.

62. The apparatus of claim 61 wherein t-Δ₁ represents a time Δ₁ sample periods before time t.

63. The apparatus of claim 61 wherein Δ₁ represents ¼ of a period of a fundamental frequency of said electrical entity.

64. The apparatus of claim 61 further comprising means for determining a fundamental frequency of said electrical entity and setting Δ₁ in response to said fundamental frequency.

65. The apparatus of claim 59 further comprising means for canceling contributions of harmonics included in said first suppressed harmonic representation.

66. The apparatus of claim 65 wherein said means for canceling contributions of harmonics comprises means for storing successive ones of said first suppressed harmonic representation and means for summing particular ones of said successive ones of said first suppressed harmonic representation.

67. The apparatus of claim 66 wherein said means for storing successive ones of said first suppressed harmonic representation comprises a first-in-first-out buffer for storing said first suppressed harmonic representation.

68. The apparatus of claim 67 wherein said means for summing particular ones of said successive ones of said first suppressed harmonic representation comprises means for separately summing a component of a first suppressed harmonic representation associated with time t, with a component of a first suppressed harmonic representation associated with time t-Δ₂ to produce a second suppressed harmonic representation of said two-axis rotating reference frame representation.

69. The apparatus of claim 68 wherein t-Δ₂ represents a time Δ₂ sample periods before time t.

70. The apparatus of claim 68 wherein Δ₂ represents 1/24 of a period of a fundamental frequency of said electrical entity.

71. The apparatus of claim 68 further comprising means for determining a fundamental frequency of said electrical entity and setting Δ₂ in response to said fundamental frequency.

72. A method of canceling contributions of harmonics included in a succession of two-axis rotating reference frame representations of an electrical entity in a multiple phase AC electric power system, the method comprising:
associating successive ones of said two-axis rotating reference frame representations with respective times t; and
separately summing components of a two-axis rotating reference frame representation associated with time t, with corresponding components of a two-axis rotating reference frame representation associated with time t-Δ₁, to produce a first suppressed harmonic representation of said two-axis rotating reference frame representations.

73. The method of claim 72 wherein associating comprises storing successive ones of said two-axis rotating reference frame representations in a first-in-first-out buffer.

74. The method of claim 73 wherein t-Δ₁ represents a time Δ₁ sample periods before time t.

75. The method of claim 73 wherein Δ₁ represents ¼ of a cycle of a fundamental frequency of said electrical entity.

76. The method of claim 73 further comprising determining a fundamental frequency of said electrical entity and setting Δ₁ in response to said fundamental frequency.

77. The method of claim 72 further comprising canceling contributions of harmonics included in said first suppressed harmonic representation.

78. The method of claim 77 wherein canceling contributions of harmonics comprises storing successive ones of said first suppressed harmonic representation and summing particular ones of said successive ones of said first suppressed harmonic representation.

79. The method of claim 78 wherein storing said successive ones of said first suppressed harmonic representation comprises storing said first suppressed harmonic representation in a first-in-first-out buffer.

80. The method of claim 79 wherein summing particular ones of said successive ones of said first suppressed harmonic representation comprises separately summing a component of a first suppressed harmonic representation associated with time t, with a component of a first suppressed harmonic representation associated with time t-Δ₂ to produce a second suppressed harmonic representation of said component of said first suppressed harmonic representation.

81. The method of claim 80 wherein t-Δ₂ represents a time Δ₂ sample periods before time t.

82. The method of claim 81 wherein Δ₂ represents 1/24 of a period of a fundamental frequency of said electrical entity.

83. The method of claim 80 further comprising determining a fundamental frequency of said electrical entity and setting Δ₂ in response to said fundamental frequency.
